(19) United States
(12) Patent Application Publication
(10) Pub. No.: US 2024/0243145 A1
(43) Pub. Date: Jul. 18, 2024

(54) IMAGING ELEMENT AND ELECTRONIC DEVICE

(71) Applicant: Sony Semiconductor Solutions Corporation, Kanagawa (JP)

(72) Inventors: Masashi Nakata, Kanagawa (JP); Junichi Kanai, Kanagawa (JP); Shinichiro Noudo, Kumamoto (JP)

(21) Appl. No.: 18/556,752

(22) PCT Filed: Feb. 18, 2022
(86) PCT No.: PCT/JP2022/006705

§ 371 Date: Oct. 23, 2023

(30) Foreign Application Priority Data
May 17, 2021 (JP) 2021-083398

(51) Int. Cl. H01L 27/146

(52) U.S. Cl. CPC H01L 27/14623; H01L 27/14627; H01L 27/14636

(57) ABSTRACT

[Problem] To improve image quality.

[Solution] An imaging element includes pixels and a pixel array. The pixel includes a light receiving element that photoelectrically converts incident light and outputs an analog signal based on light intensity. The pixel array has the pixels disposed in an array. Some of the pixels belonging to the pixel array have a light-shielding structure for blocking part of light entering the light receiving element. The light-shielding structure limits an incident angle of light entering the light receiving element.

### TECHNICAL FIELD

The present disclosure relates to an imaging element and an electronic device.

### BACKGROUND ART

In a device including a display, for example, a smartphone, the arrangement of a camera module under the display is examined. In such a camera module, when imaging is performed through a display in an environment having a low-intensity light source, the diffraction of the display may cause a flare that is a serious problem. Such a flare can be corrected by PSF (Point Spread Function) correction but can be more accurately corrected by identifying the shape of the light source.

In order to estimate the shape of a light source, imaging is performed with an ultra-short charge-storage shutter. However, it is known that an extreme short-charge-storage image that identifies the shape of a light source may deteriorate an SNR (Signal to Noise Ratio) when being used as an HDR (High Dynamic Range) image. Unfortunately, the synthesis of an HDR image may require a memory frame or flare processing in a sensor may increase the circuit size. Because of a time difference between short charge storage and long charge storage, a time difference may occur between the detection of the shape of a light source and a normal image and adversely affect video imaging.

### CITATION LIST

### Patent Literature

[PTL 1] JP 2010-273378A

### SUMMARY

### Technical Problem

Hence, the present disclosure provides an imaging element that improves image quality.

### Solution to Problem

According to an embodiment, an imaging element includes pixels and a pixel array. The pixel includes a light receiving element that photoelectrically converts incident light and outputs an analog signal based on light intensity. The pixel array has the pixels disposed in an array. Some of the pixels belonging to the pixel array have a light-shielding structure for blocking part of light entering the light receiving element.

The light-shielding structure may limit an incident angle of light entering the light receiving element of the pixel having the light-shielding structure.

The light-shielding structure may be a light-shielding film provided for the light receiving element.

The light-shielding structure, in the pixels, may be formed with an opening having a size equal to or smaller than 25% of the area of the surface of the light receiving element.

An opening formed by the light-shielding structure may be identical or different in size among the pixels.

The opening formed by the light shielding structure may be provided at the same relative position or different relative positions in the pixels.

In the pixel, one or more openings may be formed by the light-shielding structure.

The light-shielding structure may be a polarizer provided on the entry face side of the light receiving element.

The pixels different from the pixels having the light shielding structure may include the pixel having a plasmon filter disposed on the entry face side of the light receiving element.

The pixels having the light-shielding structure may be disposed without being adjacent to each other in the pixel array.

The pixels having the light-shielding structure may be periodically disposed in the pixel array.

Each of the pixels may include an on-chip lens, and the pixel array may include a module lens.

The pixel may include separate pixels obtained by dividing the light receiving element belonging to the pixel into a plurality of pixels, and the pixel having the light-shielding structure may be provided with the light-shielding structure for at least one of the separate pixels.

A signal processing circuit that converts an analog signal outputted from the light receiving element into a digital signal may be further provided.

The signal processing circuit may detect a shape of a light source on the basis of an output from the pixel having the light-shielding structure.

The signal processing circuit may correct the digital signal on the basis of the shape of the light source.

If the plasmon filter is provided, the signal processing circuit may estimate the light source on the basis of an output from the pixel having the light-shielding structure.

According to an embodiment, an electronic device includes the imaging element according to any one of the descriptions, and a display that has a display surface for displaying information on the entry face side of the imaging element, wherein the imaging element converts, by photoelectric conversion, light received through the display.

The pixel may be provided such that an incident angle allowing the entry of light is controlled to 50% or less of a typical incident angle by the light-shielding structure, and imaging information about an adjacent object may be generated on the basis of an output from the pixel having the light-shielding structure.

Biometric information may be obtained through the display on the basis of an output from the pixel having the light-shielding structure.

The biometric information may be information including any one of a fingerprint, a high court, a vein, a skin, hemoglobin, and oxygen saturation.

Image quality deteriorated by the display may be restored on the basis of an output from the pixel having the light-shielding structure.

Information about a bar code may be acquired on the basis of an output from the pixel having the light-shielding structure.

The plurality of imaging elements may be provided.

In the plurality of imaging elements, the wiring layout of the display in at least one of the imaging elements may be different from the wiring layout of the display in the other imaging elements.

### BRIEF DESCRIPTION OF DRAWINGS

FIG. 1 schematically illustrates an electronic device according to an embodiment.

FIG. 2 schematically illustrates the pixel array of an imaging element according to the embodiment.

FIG. 3 schematically illustrates an example of the layout of pixels according to the embodiment.

FIG. 4 illustrates an example of the placement of a light-shielding pixel according to the embodiment.

FIG. 5 illustrates an example of the placement of the light shielding pixel according to the embodiment.

FIG. 6 illustrates an example of the placement of the light-shielding pixel according to the embodiment.

FIG. 7 illustrates an example of the placement of the light-shielding pixel according to the embodiment.

FIG. 8 illustrates an example of the placement of the light-shielding pixel according to the embodiment.

FIG. 9 illustrates an example of the placement of the light-shielding pixel according to the embodiment.

FIG. 10 illustrates an example of the placement of the light-shielding pixel according to the embodiment.

FIG. 11 illustrates an example of an image captured according to the embodiment.

FIG. 12 illustrates an example of a detected shape of a light source according to the embodiment.

FIG. 13 illustrates estimated flare according to the embodiment.

FIG. 14 illustrates an example of an image where flare has been removed according to the embodiment.

FIG. 15 is a block diagram schematically illustrating the imaging element according to the embodiment.

FIG. 16 illustrates an example of the openings of light-shielding pixels in a pixel array according to an embodiment.

FIG. 17 illustrates an example of the openings of the light-shielding pixels in the pixel array according to the embodiment.

FIG. 18 illustrates an example of the openings of the light-shielding pixels in the pixel array according to the embodiment.

FIG. 19 schematically illustrates an electronic device according to an embodiment.

FIG. 20 schematically illustrates an example of the layout of pixels according to an embodiment.

FIG. 21 schematically illustrates an example of the layout of pixels according to an embodiment.

FIG. 22 illustrates an example of the placement of the pixel according to the embodiment.

FIG. 23 schematically illustrates an example of the layout of the pixels according to the embodiment.

FIG. 24 schematically illustrates an example of the layout of the pixels according to the embodiment.

FIG. 25 schematically illustrates a plasmon filter.

FIG. 26 indicates an example of the characteristics of the plasmon filter.

FIG. 27 schematically illustrates an example of the layout of pixels according to the embodiment.

FIG. 28 schematically illustrates an example of the layout of the pixels according to the embodiment.

FIG. 29 illustrates a placement example of an imaging element according to the embodiment.

FIG. 30 illustrates a placement example of the imaging element according to the embodiment.

FIG. 31 illustrates a placement example of the imaging element according to the embodiment.

FIG. 32A illustrates a state of the interior of a vehicle from the rear to the front of the vehicle.

FIG. 32B illustrates a state of the interior of the vehicle diagonally from the rear to the front of the vehicle.

FIG. 33A is a front view illustrating a digital camera as a second application example of the electronic device.

FIG. 33B is a rear view of the digital camera.

FIG. 34A is an outside drawing illustrating an HMD as a third application example of the electronic device.

FIG. 34B is an outside drawing of a smart glass.

FIG. 35 is an outside drawing illustrating a TV as a fourth application example of the electronic device.

FIG. 36 is an outside drawing illustrating a smartphone as a fifth application example of the electronic device.

### DESCRIPTION OF EMBODIMENTS

Embodiments of the present disclosure will be described below with reference to the accompanying drawings. The drawings are used for the description and do not always agree with the shapes and sizes of the configurations of units in an actual device or size ratios or the like relative to other configurations in the actual device. Since the drawings are simplified, configurations that are not illustrated but are necessary for implementation are to be properly provided.

### First Embodiment

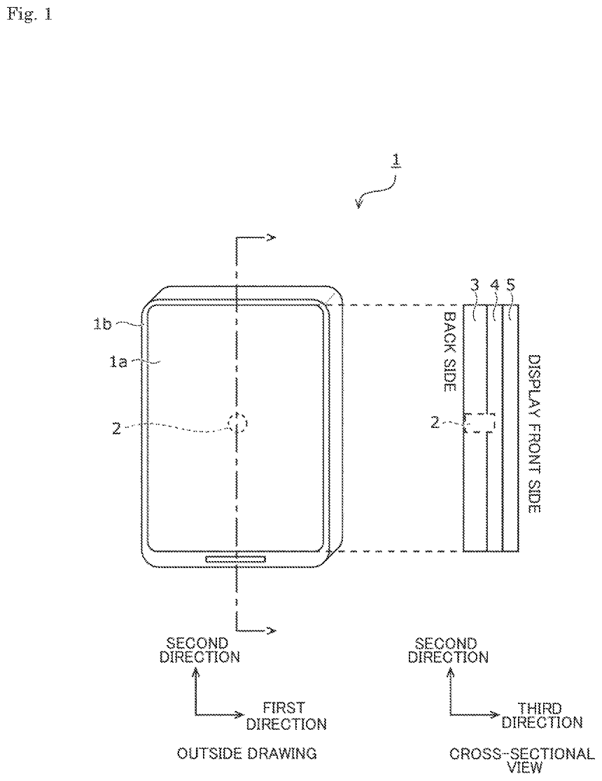

FIG. 1 illustrates an outside drawing and a cross-sectional view of an electronic device in a schematic form according to an embodiment. An electronic device 1 is an electronic device having a display function and a shooting function, for example, a smartphone, a cellular phone, a tablet, or a PC. The electronic device 1 is not limited to these examples and may be other devices, for example, an imaging device such as a camera, a medical device, or an inspection device. As illustrated in FIG. 1, a first direction, a second direction, and a third direction are defined for the sake of convenience. The electronic device 1 includes an imaging element 2, a component layer 3, a display 4, and a cover glass 5.

Hereinafter, as illustrated in FIG. 1, the negative side of the display 4 in the third direction may be referred to as under the display. For example, the imaging element 2 may be referred to as an under-display imaging element.

As illustrated in the outside drawing, for example, the electronic device 1 includes a display area 1a and a bezel 1b. The electronic device 1 displays an image or video (hereinafter may be referred to as an image or the like) in the display area 1a. The bezel 1b may include a so-called built-in camera for capturing an image on the display surface side of the display. At present, in many cases, a smaller area is demanded of the bezel 1b. Thus, the electronic device 1 according to the present embodiment includes the imaging element 2 under the display, so that the area of the bezel 1b is reduced on the display surface side.

The imaging element 2 includes a signal processing circuit that performs signal processing on a light receiving element and a signal outputted by the light receiving element. The imaging element 2 acquires information about an image on the basis of light received by the light receiving element. The imaging element 2 may be placed with a semiconductor formed by a plurality of layers. The details of the imaging element 2 will be described later. In FIG. 1, the imaging element 2 is circular in shape. The shape of the imaging element 2 is not limited thereto. Another example of the unrestricted shape is a rectangle. Any other shapes may be used instead.

The component layer 3 is a layer including the imaging element 2. The component layer 3 includes, for example, various modules and devices for implementing processing other than imaging in the electronic device 1.

The display 4 is a display for outputting an image or the like. As illustrated in the cross-sectional view, the imaging element 2 and the component layer 3 are provided on the back side of the display 4. As illustrated in FIG. 1, the imaging element 2 is provided into the display 4.

The cover glass 5 is a glass layer that protects the display 4. Between the display 4 and the cover glass 5, a polarizing layer or the like may be provided to allow a user to properly view light outputted from the display 4 or a layer acting as a touch panel in any form (voltage-type, electrostatic) may be provided to use the display area 1a as a touch panel. In addition, any layer may be provided between the display 4 and the cover glass 5 in such a way as to properly perform imaging in the imaging element 2 and provide display on the display 4.

The light receiving element, a lens, and a circuit or the like on, for example, a semiconductor layer are not essential configurations in the present disclosure and thus the specific placement thereof will not be discussed in the following description. The placement can be made using any method for shapes and configurations that are suggested in the drawings and the description or the like. For example, the control of the imaging element and the acquisition of a signal can be implemented by any method unless otherwise specified.

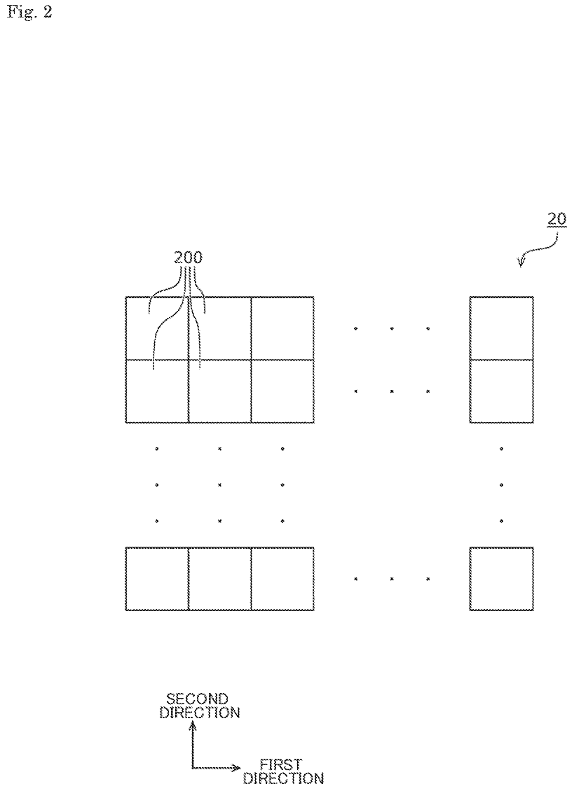

FIG. 2 illustrates a sparse array provided in the imaging element 2. The imaging element 2 includes a pixel array 20 as a light receiving area. The pixel array 20 includes a plurality of pixels 200. The pixels 200 are provided in, for example, an array in the first direction and the second direction. Note that the directions are merely exemplary and are not limited to the first direction and the second direction. Other examples of the unrestricted direction include directions shifted by 45° from the first direction and the second direction or directions shifted by any angles from the first direction and the second direction.

The pixels 200 may be light receiving pixels configured to receive light of predetermined colors. Examples of colors acquired by the pixels 200 include, but are not limited to, primary colors of R(red), G(green), and B(blue). Another example of colors is, but not limited to, at least one of three colors: Cy(cyan), Mg(magenta), and Ye(yellow). Some of the pixels 200 may receive the intensity of W(white) light. The color may be received by the light receiving element with, for example, a color filter provided on the entry face of the light receiving element or an organic photoelectric conversion film provided on the light receiving element. Additionally, an infrared cut filter may be used as a filter.

In the pixel 200, an analog signal photoelectrically converted for each color by the light receiving element is properly converted into a digital signal by an A/D (Analog to Digital) converter circuit provided in or outside the imaging element 2. A circuit constituting a path to the A/D converter circuit and the A/D converter circuit may be equivalent to a typical CMOS (Complementary Metal Oxide Semiconductor) sensor and thus the details thereof are omitted. For example, an A/D converter circuit is provided for each pixel or each column. The analog signal outputted by the pixel 200 is properly converted into a digital signal and then is outputted. The digital signal is outputted to a proper circuit through a path equivalent to that of a typical circuit.

FIG. 3 illustrates some of the pixels 200 of the pixel array 20 according to the embodiment. As illustrated in FIG. 3, for example, the pixels 200 may be configured such that light of the same color is received by a set of four pixels. Examples of the layout of the pixels 200 include, but not limited to, a Bayer layout including sets of four pixels. In addition, the pixels may be arranged in a checkered pattern. The layout of colors is not limited to these examples if the colors are properly mosaicked.

The pixels 200 include 2 by 2 pixels for receiving R, 2 by 2 pixels for receiving G, and 2 by 2 pixels for receiving B as illustrated in FIG. 3. A shaded pixel is a light-shielding pixel 202 having a light-shielding structure. The light-shielding pixel 202 receives light while partially blocking the light entering from the entry face side, and converts the intensity of the light into an analog signal in a shielding state. Other pixels 200 are ordinary pixels that photoelectrically convert light received through color filters or the like.

For example, the light-shielding pixel 202 is not disposed next to the pixels (eight consecutive pixels) in the vertical, horizontal, and diagonal directions. Alternatively, the light-shielding pixels 202 may be periodically disposed in the pixel array 20.

In FIG. 3, the light-shielding pixel 202 is not included in a group of pixels for receiving G light. The layout is not limited thereto. For example, the light-shielding pixel 202 may be at least one of the pixels for receiving G light.

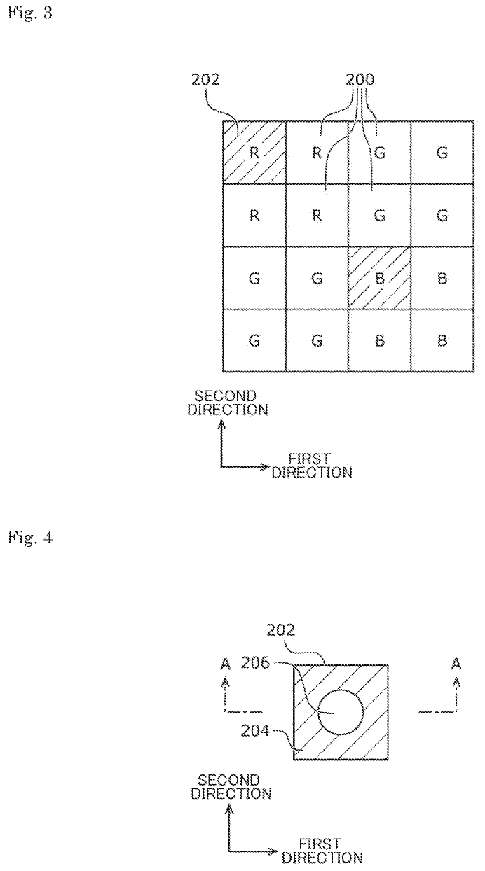

FIG. 4 schematically illustrates an example of the light-shielding pixel 202. The light-shielding pixel 202 includes, for example, a light-shielding film or an absorbing film as a light-shielding structure. In the example of FIG. 4, the light-shielding pixel 202 includes a light-shielding film 204 and an opening 206.

The light-shielding film 204 (or the absorbing film) is formed by a film that blocks light of an overall visible-light region or light in the wavelength region of a color of light received by the light-shielding pixel 202. Examples of the material of the light-shielding film 204 include, but not limited to, a proper metal or an organic substance of a color filter or the like that features the absorption of a proper wavelength region. For example, if the pixel array 20 includes a dummy pixel for acquiring a signal of a dark region, the light-shielding film 204 may be a thin film or a thick film that is made of the same material as a light-shielding structure used for the dummy pixel.

The light-shielding film 204 including the opening 206 limits the region of light incident on the light receiving element of the light-shielding pixel 202. In the light-shielding pixel 202, light entering through the opening 206 is photoelectrically converted, and an analog signal is outputted on the basis of the intensity of the light entering through the opening 206.

For example, the size of the opening 206 formed by the light-shielding film 204 may be, but not limited to, 25% or less of the area of the light receiving region of the light receiving element. For example, if the rectangular opening 206 is formed by the light-shielding film 204 in the light-shielding pixel 202 such that the area of the light receiving surface of the light receiving region is reduced to a half in the first direction and the second direction, the opening 206 has the size of 25% or less.

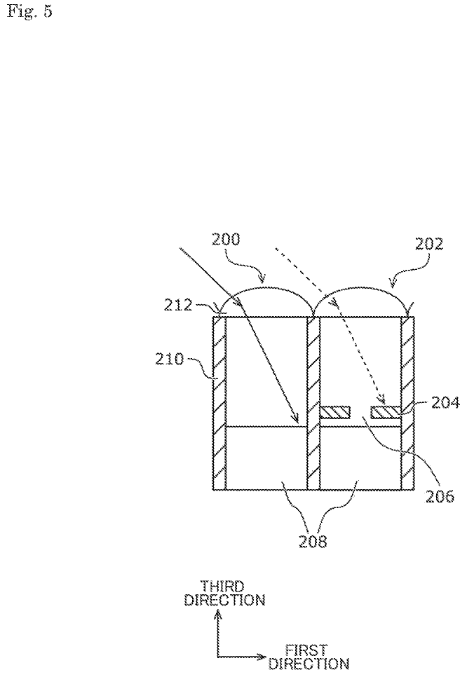

FIG. 5 illustrates an A-A section in which the light-shielding pixel 202 in FIG. 4 is viewed in the second direction. The adjacent pixel 200 is also illustrated.

The pixel 200 and the light-shielding pixel 202 each has a light receiving region 208. According to the intensity of light entering the entry face side of the light receiving region 208, the light receiving element performs photoelectric conversion and outputs an analog signal corresponding to the intensity of received light. The light receiving region 208 is formed by, for example, a photodiode or an organic photoelectric conversion film.

The pixel 200 and the light-shielding pixel 202 are shielded by a light shielding wall 210. The light-shielding wall 210 may be, for example, a metal film. The light-shielding wall 210 is a wall surface for preventing light entering the pixel 200 and the light-shielding pixel 202 from leaking to other pixels 200 and light-shielding pixels 202. For example, the light-shielding wall 210 facing the pixel 200 desirably has a reflecting surface in order to properly acquire the intensity of light entering the pixel 200. In contrast, the light-shielding wall 210 facing the light-shielding pixel 202 desirably has an unreflecting surface in order to prevent an increase in the angle of light entering the light-shielding pixel 202. The configuration is not limited thereto. Since the entry of light reflected by the light-shielding wall 210 into the opening 206 can be controlled by an optical system, the light-shielding wall 210 facing the light-shielding pixel 202 may have a reflecting surface.

The pixel 200 and the light-shielding pixel 202 each have an on-chip lens 212. The pixel 200 and the light-shielding pixel 202 each allow the entry of light into the light receiving region through the on-chip lens 212.

As illustrated in FIG. 5, in the light-shielding pixel 202, the light-shielding film 204 partially prevents the entry of light into the light receiving region 208 through the on-chip lens 212. Solid-line arrows into the pixel 200 and dotted-line arrows into the light-shielding pixel 202 indicate the entry of light at a certain angle. Actually, light is refracted twice at the boundary surface of the on-chip lens 212. For the sake of simplicity, directions before and after passage through the on-chip lens 212 are indicated by arrows.

For example, as illustrated in FIG. 5, light incident on the pixel 200 at an angle indicated by a solid line is refracted by the on-chip lens 212 and enters the light receiving region 208. In contrast, light incident with the same angle at the same position on the on-chip lens 212 in the light-shielding pixel 202 is blocked by the light-shielding film 204 and does not enter the light receiving region 208.

In this way, the light-shielding film 204 is used as a light-shielding structure, thereby limiting the incident angle of light entering the light receiving region 208 through the opening 206. In the event of flare caused by a display or the like, for example, the incident angle of light entering the light receiving region in the light-shielding pixel 202 can be set at 50% or less of the incident angle of light entering the light receiving region in the pixel 200. The incident angle is not limited thereto. In addition, any incident angle may be properly set on the basis of the layout and shape of the on-chip lens and the opening 206 on the light-shielding film 204.

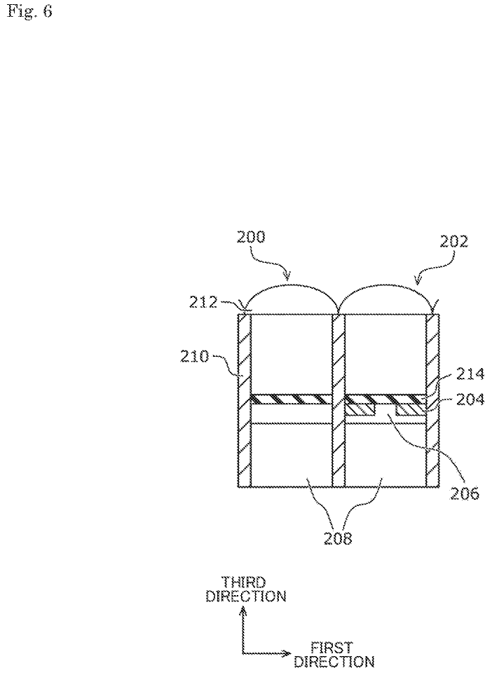

FIGS. 6, 7, and 8 are cross-sectional views illustrating other examples of the pixel 200 and the light-shielding pixel 202. The configuration is not limited to these examples. As described above, the pixel 200 and the light-shielding pixel 202 receive light in the wavelength region of a proper color through a color filter or the like. These drawings illustrate examples in which color filters are provided for the pixel 200 and the light-shielding pixel 202.

In FIG. 6, a color filter 214 is provided on the light-shielding film 204. With this configuration, light entering the opening 206 of the light-shielding film 204 may be converted to light limited to a desired wavelength region. In the case where the color filter 214 is provided on the light-shielding film 204, the color filter 214 does not need to be disposed next to the light-shielding film 204 as illustrated in FIG. 6. A proper interlayer insulating film or the like may be provided between the color filter 214 and the light-shielding film 204.

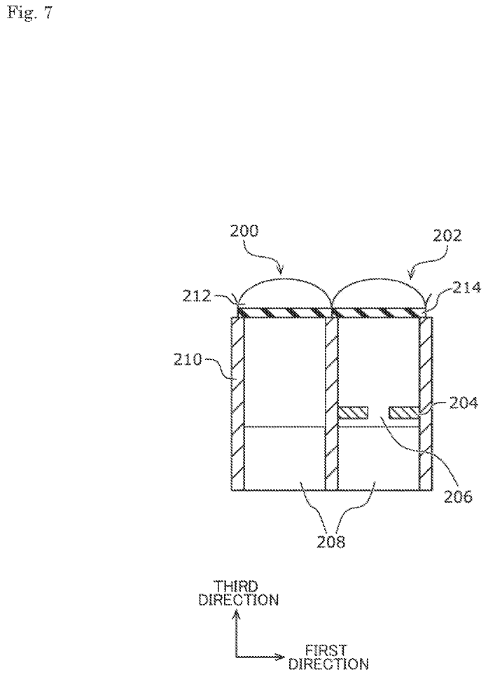

FIG. 7 illustrates another example of the color filter 214 provided on the light-shielding film 204. As illustrated in FIG. 7, the color filter 214 may be provided next to the on-chip lens 212.

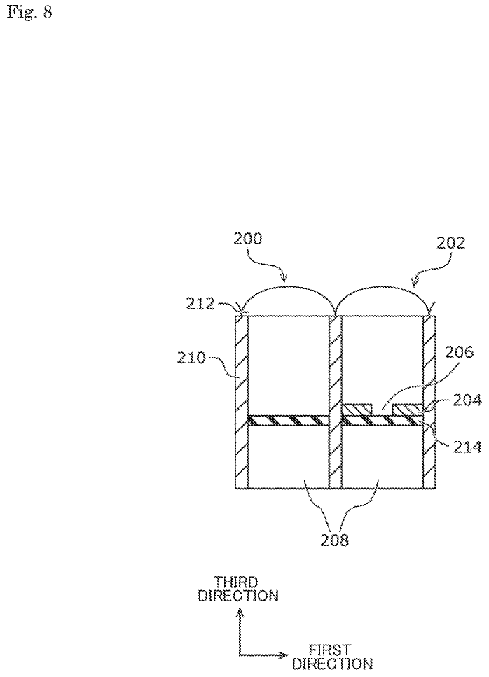

FIG. 8 illustrates an example where the color filter 214 is provided under the light-shielding film 204. As illustrated in FIG. 8, light having passed through the opening 206 of the light-shielding film 204 may enter the light receiving region 208 through the color filter 214.

Also in the case where the color filter 214 is provided under the light-shielding film 204, an interlayer insulating film or the like may be provided between the light-shielding film 204 and the color filter 214 as in the case where the color filter 214 is provided on the light-shielding film 204. Alternatively, an interlayer insulating film or the like may be provided between the color filter 214 and the light receiving region 208.

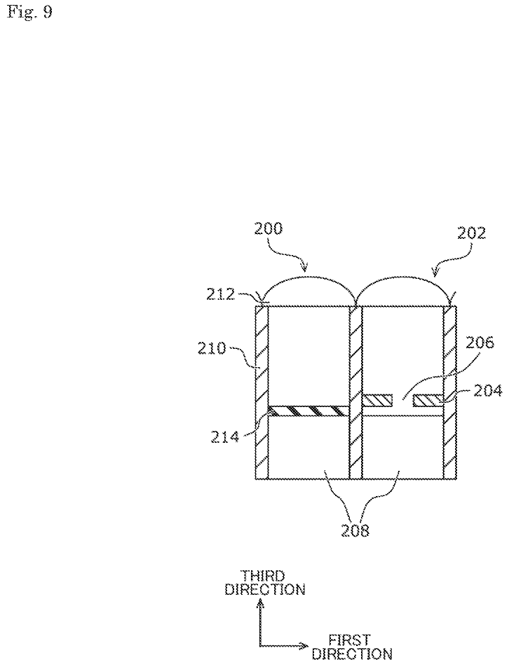

FIG. 9 illustrates another example of the layout of the color filter 214 in the pixel 200 and the light-shielding pixel 202. As illustrated in FIG. 9, the pixel 200 to receive light in a proper color in the light receiving region 208 may be provided with the color filter 214, whereas the light-shielding pixel 202 to receive white light may be configured without the color filter.

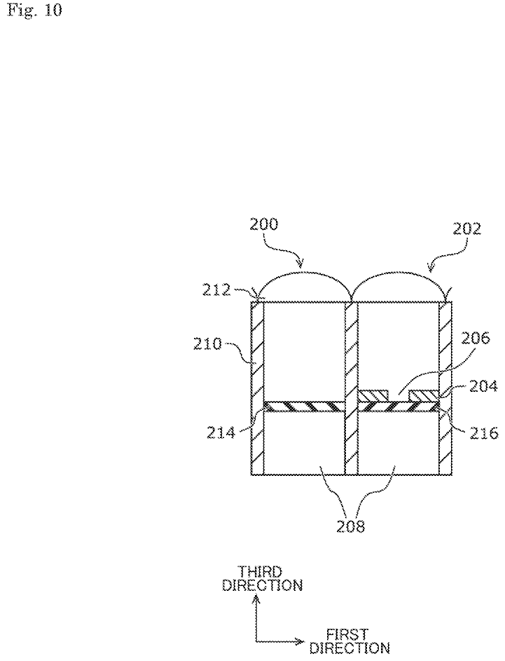

FIG. 10 illustrates another example of the layout of the filter in the pixel 200 and the light-shielding pixel 202. The pixel 200 may be provided with the color filter 214 while the light-shielding pixel 202 may be provided with an ND filter 216 (Neutral Density filter). The provision of the ND filter 216 can limit the incident angle of light entering the light shielding pixel 202 and more properly control the intensity of incident light. In this way, the intensity of received light may be controlled by the ND filter 216 as well as the size of the opening 206.

In the light-shielding pixel 202, as described above, the incident angle of light and the incident area (incident intensity) of light in the light receiving region are set smaller (lower) than those of the ordinary pixel 200. Thus, in the light-shielding pixel 202, light from a light source can be acquired as low-luminance information without shutter control or exposure control. In other words, also in the presence of a high intensity light source near the display, the imaging element 2 can obtain a signal for detecting the shape of the light source by acquiring information from the light-shielding pixel 202.

FIGS. 8 to 10 illustrate the filter provided under the light-shielding film 204. The configuration is not limited thereto. Also in such a filter configuration, the filter may be provided on or above the light-shielding film 204 as illustrated in FIGS. 5 to 7.

FIG. 11 illustrates an example of an image captured in the imaging element 2 in the presence of a high-intensity light source near an imaging surface. A shaded area is an area where an image is properly captured, whereas an empty area is an area where an image is improperly captured because of flare. In the presence of a high-intensity light source near the imaging surface (for example, near the display 4 in FIG. 1), flare may occur around the position of the light source. In FIG. 11, flare is emphasized to be noticeable. In reality, the influence of flare may decrease with a distance from the center position of the light source.

In this case, an image cannot be properly captured and thus the influence of flare is desirably reduced by signal processing or image processing. Hence, the influence of flare is reduced by signal processing or image processing on the basis of the shape of the light source, the shape being acquired from the light-shielding pixel 202. Specifically, a correction is made through a PSF by using the shape of the light source, the shape being detected by the light-shielding pixel 202.

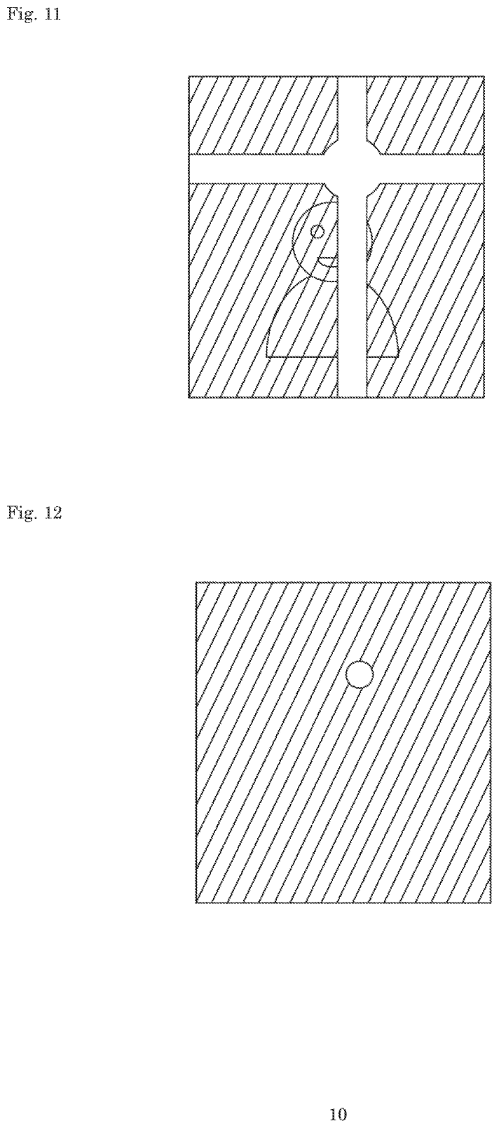

FIG. 12 illustrates an example of the shape of the light source, the shape being detected from an image captured from the light-shielding pixel 202 when the image of FIG. 11 is captured in the imaging element 2. In the light-shielding pixel 202, the intensity of light entering the light receiving element is limited, so that light can be received from the high-intensity light source and the influence of other reflected light from an object or the like can be reduced. Thus, on the basis of the signal acquired by the light-shielding pixel 202, the shape of the light source can be detected as illustrated in FIG. 12. For example, the shape of the light source may be detected by binarizing an image signal, which is obtained on the basis of the signal from the light-shielding pixel 202, by using a static or dynamic threshold value.

FIG. 13 illustrates an image with the influence of flare, the influence being estimated on the basis of the PSF according to the shape of the light source of FIG. 12 and the intensity of light of the light source. The influence of flare may be obtained on the basis of, for example, a PSF obtained by imaging light of high intensity in advance. For example, information about a PSF may be acquired in advance and then the influence of flare may be estimated by a convolution of the information about the PSF and the light source.

As another example, light sources in various shapes at various intensity levels may be imaged in various environments and then a neural network model may be learned through machine learning by using the shapes, intensity information, and acquired flare images as teacher data. The machine learning may include any method, for example, any method for deep learning. Thereafter, the influence of flare may be inferred on the basis of the shape of the light source and the intensity information. The shape of the light source is detected on the basis of a signal outputted from the light-shielding pixel 202 to the neural network model. The neural network model may be a model with at least one layer formed by a convolution layer. When a neural network model is used, the influence of a ghost that may occur in the same situation may be corrected in addition to the influence of flare.

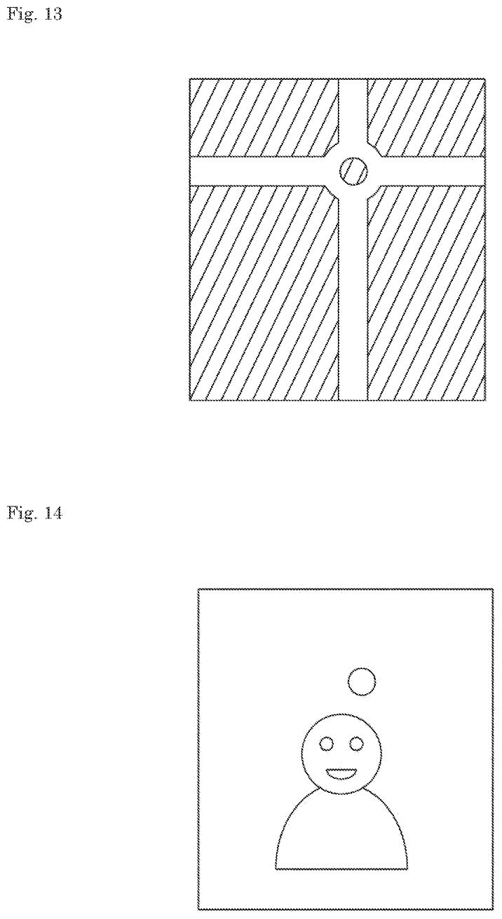

FIG. 14 illustrates an example of an image after the influence of flare is eliminated. For example, an image in which the influence of flare has been properly eliminated as illustrated in FIG. 14 can be obtained by subtracting the image of FIG. 13 from the image of FIG. 11.

For example, if a color filter is not provided for the opening 206 as illustrated in FIG. 9, the shape of the light source is obtained as white light, thereby eliminating the influence of flare caused by white light.

If the color filter 214 is provided for the opening 206 as illustrated in FIG. 8, the shape of the light source is obtained in each color through the color filter 214 provided in the light-shielding pixel 202, thereby eliminating the influence of flare caused by the color.

In this case, for example, the color filter 214 provided in the light-shielding pixel 202 may be disposed in a Bayer layout regardless of the color of a pixel group including the light-shielding pixel 202. As a matter of course, the G pixels of FIG. 3 may include the light-shielding pixel 202, and the color filter 214 may be provided in the same color as a pixel group including the light-shielding pixel 202.

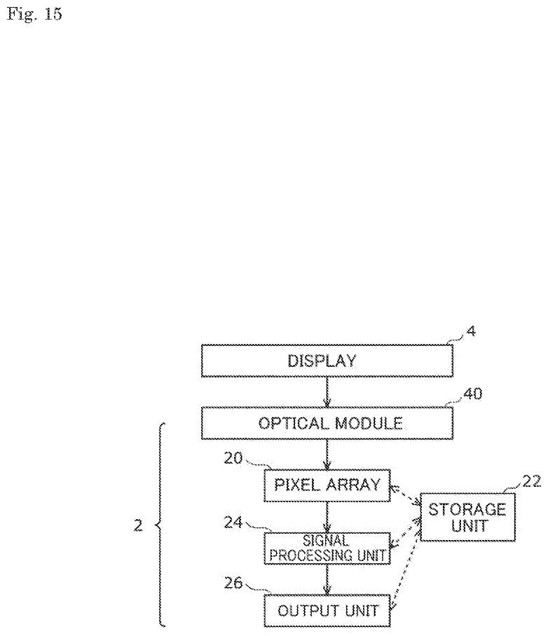

FIG. 15 is a block diagram schematically illustrating the imaging element 2 according to the embodiment. The imaging element 2 includes the pixel array 20, a storage unit 22, a signal processing unit 24, and an output unit 26. Moreover, an optical module 40 provided for the display 4 may be partially placed as the imaging element 2.

The optical module 40 includes, for example, an opening disposed on the material of the display 4, and a module lens. The optical module 40 is a module for properly passing light from the display surface of the display 4 into the pixel array 20. The optical module 40 may be properly provided with an infrared cut filter or the like.

The opening may be provided with a polarizing plate or the like. The module lens is a lens for properly passing light into the pixel array 20 after the opening. The module lens is provided in addition to the on-chip lens 212.

The pixel array 20 includes the pixels 200 and the light-shielding pixels 202 that have the structures of FIGS. 3 to 10 and are disposed in an array as illustrated in FIG. 2.

The storage unit 22 includes a memory or a storage that properly stores information to be stored in the imaging element 2.

The signal processing unit 24 is formed by using, for example, a signal processing circuit and properly processes analog signals outputted from the pixel 200 and the light-shielding pixel 202 before outputting the signals.

The output unit 26 properly outputs the signal processed by the signal processing unit 24 to the outside or stores the signal in the storage unit provided in the imaging element.

Furthermore, the imaging element 2 is properly provided with constituent elements necessary for operations, for example, a control unit for controlling the configurations of the imaging element 2.

The processing of the signal processing unit 24 will be described below. The signal processing unit 24 includes, for example, an A/D converter circuit that converts an analog signal outputted from the pixel array 20 into a digital signal and a logic circuit that converts the digital signal into a signal suitable for an output.

The analog signal photoelectrically converted in the pixel 200 and the light-shielding pixel 202 of the pixel array 20 is converted into a digital signal (digital image signal) by the A/D converter circuit of the signal processing unit 24 and is outputted. If subsequent signal processing and image processing are not necessary, the digital image signal is outputted through the output unit 26.

In the present embodiment, the image signal that has been converted by the A/D converter circuit and outputted from the light-shielding pixel 202 is used for detecting the shape of the light source. Specifically, the signal processing unit 24 reconstructs a high-luminance image from image signals obtained by thinning from the light-shielding pixel 202. From the reconstructed image, as described above, the shape of the light source is detected by using, for example, any threshold value. The signal processing unit 24 may detect the intensity of light of the light source along with the shape of the light source.

The signal processing unit 24 for acquiring the shape of the light source may perform processing for interpolating pixels at the positions of the light-shielding pixels 202 in an image on the basis of the image signals outputted from the pixel 200 and the light-shielding pixel 202. This processing can interpolate pixel values in the light-shielding pixels 202 having light-shielding structures. For the interpolation, a typical defect correction method can be used. At this point, an image signal in which the influence of flare or the like has not been eliminated, for example, image information in FIG. 11 can be obtained.

The signal processing unit 24 calculates the influence of flare or the like on the basis of the shape of the light source, the shape being acquired from the light-shielding pixel 202. Through the calculation of the influence, the signal processing unit 24 obtains image information indicating the influence of flare or the like as illustrated in FIG. 13.

The signal processing unit 24 then subtracts image information about the influence of flare or the like from image information in which the influence of flare or the like has not been eliminated, thereby obtaining image information in which the influence of flare or the like has been eliminated as illustrated in FIG. 14.

The signal processing unit 24 performs processing necessary for obtaining other proper image signals. Processing for obtaining data suitable for display, for example, demosaicing or linear matrix processing may be performed or processing including various kinds of filtering may be performed.

In the foregoing description, the signal processing unit 24 (signal processing circuit) performs the entire processing. The signal processing unit 24 may include an A/D conversion unit (A/D converter circuit), a light-source shape detection unit (light-source shape detection circuit), a light-shielding pixel correction unit (light-shielding pixel correction circuit), and a flare correction unit (flare correction circuit). These circuits may be properly formed as analog circuits or digital circuits. The digital circuit may be any circuit, e.g., an ASIC (Application Specific Integrated Circuit) or an FPGA (Field-Programmable Gate Array).

As described above, according to the present embodiment, the light receiving pixel includes a light-shielding pixel having a light-shielding structure, thereby accurately eliminating the influence of flare or the like in a captured image. In the imaging element according to the present embodiment, exposure control or double exposure is not necessary, thereby efficiently obtaining a more proper image.

### Second Embodiment

In the first embodiment, as illustrated in FIGS. 3 and 4, the light-shielding film 204 having the openings 206 identical in shape and size was described. The configuration of the light-shielding pixel 202 is not limited thereto.

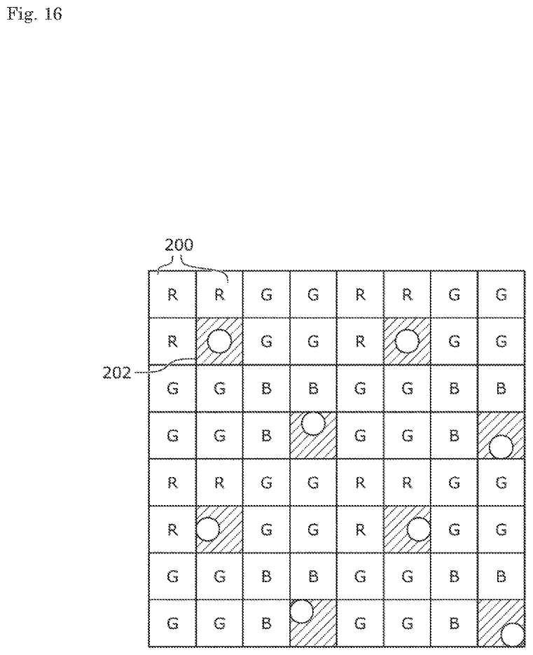

FIG. 16 illustrates a layout example of openings 206 in the light-shielding pixels 202. For example, as illustrated in FIG. 16, the light-shielding pixels 202 may be identical in shape and size with the openings 206 disposed at different positions in the pixels.

The light-shielding pixels 202 are provided with the openings 206 at different relative positions in the pixels, allowing each of the light-shielding pixels 202 to have a phase difference at a light receiving position. For example, reflected light from a subject does not cause a large phase difference depending upon the position of the pixel, whereas diffracted light on a display causes a large phase difference depending upon the position of the adjacent pixel. As a result, information about the phase difference is obtained on the basis of a signal obtained from the light-shielding pixel 202, allowing an imaging element 2 to split reflected light from the subject and diffracted light generated on a display 4.

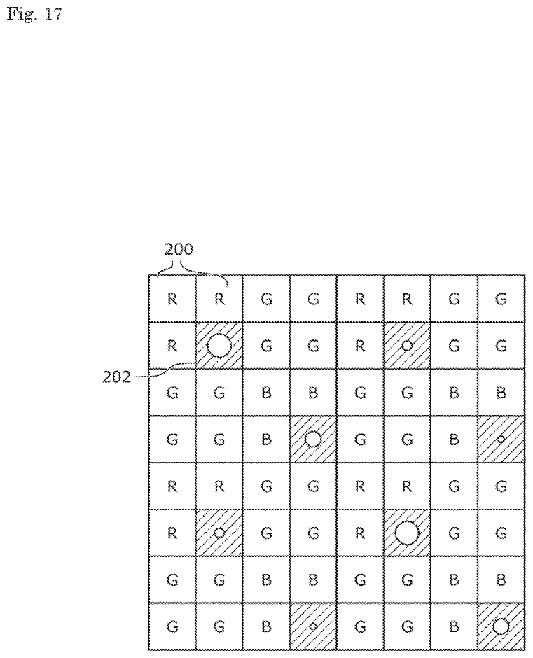

FIG. 17 illustrates a layout example of the openings 206 in the light-shielding pixels 202. For example, as illustrated in FIG. 17, the light-shielding pixels 202 may be provided with the openings 206 having different sizes at the same position in the pixels.

Restrictions on incident angles vary among the light-shielding pixels 202, thereby receiving light with different characteristics. For example, the reception of reflected light from the subject is not so affected by an incident angle if the subject is disposed at a certain distance from the imaging element 2. In contrast, diffracted light on the display 4 affects the luminance value of received light as the incident angle decreases.

More specifically, an incident angle is disturbed by adjacent diffraction or the like, so that results on whether light enters the openings 206 distinctly vary among the openings 206 having small incident angles. Thus, with the provision of the openings 206 with different incident angles, whether light received in the light-shielding pixel 202 is affected by reflection from the subject or diffraction on the display 4 can be easily determined by analyzing an image for each size of the openings 206.

FIG. 18 illustrates another layout example of the openings 206 in the light-shielding pixels 202. As shown in FIG. 18, the openings 206 having different sizes may be provided at different positions in the pixels. The openings 206 are circular in shape. The shapes are not limited to circles and may be any other shapes such as a rectangle and an ellipse.

As described above, according to the present embodiment, when the light-shielding film 204 is used as a light-shielding structure, the accuracy of detecting flare can be improved by properly changing the sizes and relative positions of the openings 206 in the pixels.

### Third Embodiment

In the foregoing embodiments, the electronic device 1 includes one imaging element 2. The configuration is not limited thereto. The electronic device 1 may include two or more imaging elements 2.

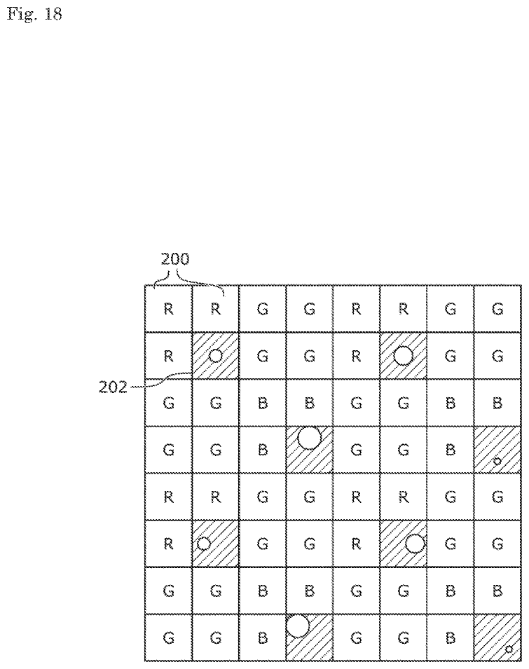

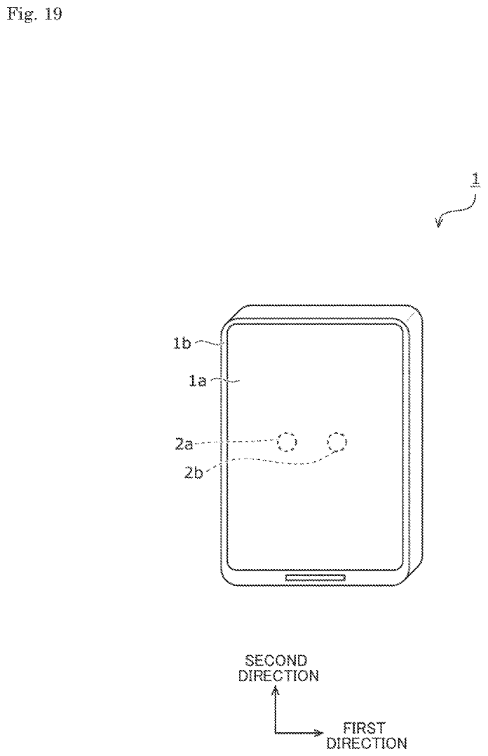

FIG. 19 is an outside drawing of an electronic device 1 according to an embodiment. The electronic device 1 includes two imaging elements 2a and 2b. In this way, the electronic device can be configured with multiple imaging elements. The electronic device 1 may include the two imaging elements 2a and 2b with different imaging characteristics. The two imaging elements 2a and 2b may have identical characteristics.

For example, the imaging element 2a may include light-shielding pixels 202 as in the foregoing description while in the imaging element 2b, pixels to serve as the light-shielding pixels 202 of the imaging element 2a may receive W in the configuration of the same pixel array as the imaging element 2a.

With this configuration, flare or the like can be removed as in the foregoing description by using the light-shielding pixels 202 of the imaging element 2a, and pixel information in an image where the light-shielding pixels 202 may become defective in the imaging element 2a can be interpolated from pixels that receive W in the imaging element 2b. Any wavelength may be acquired instead of the wavelength region of W by an infrared cut filter or the like.

In the case of imaging elements 2a and 2b having different characteristics, the configuration of the optical module 40 in FIG. 15 may be changed. For example, one of the imaging elements may be provided with an infrared cut filter and the other of the imaging elements may be provided without an infrared cut filter. For example, the imaging elements 2a and 2b may be configured with polarizing filters in different polarization directions. For example, the imaging elements 2a and 2b may be configured with module lenses with different characteristics.

If the imaging elements 2a and 2b have similar configurations, the accuracy of detecting a light source in the light-shielding pixel 202 can be improved by using a parallax. For example, diffraction on a display 4 has a large parallax and thus from the intensity of light received in the light-shielding pixel 202, a correction for reducing the influence of diffraction on the display 4 can be made in a signal processing unit 24.

Moreover, at the positions of the imaging elements 2a and 2b, the wiring pattern (wiring layout) of the display 4 can be changed regardless of whether the imaging elements 2a and 2b have similar configurations. By changing the wiring pattern thus, deteriorated image quality due to the wiring of the display 4 can be compensated for by a correction based on the outputs of the imaging elements.

For example, the imaging element 2a may be configured with a pixel array 20 in which pixels 200 and the light-shielding pixels 202 are placed in an array along a first direction and a second direction, and the imaging element 2b may be configured with an array of the pixels 200 and the light-shielding pixels 202 in directions rotated by 45° from the first direction and the second direction of the pixel array 20. For example, in the event of flare as illustrated in FIG. 11, the imaging element 2a can acquire information about the direction of the array while the imaging element 2b can acquire information about the direction rotated by 45° from the direction of the array. This can improve the detection of the shape of the light source and the accuracy of correcting a defect in the light-shielding pixel 202.

As described above, according to the present embodiment, the electronic device can be provided with a plurality of imaging elements. These imaging elements can make corrections and interpolations in images outputted to one another.

### Fourth Embodiment

In the foregoing embodiments, the light-shielding pixel 202 is formed on the light-shielding film 204. The control of the amount of light in the light-shielding pixel 202 is not limited thereto.

FIG. 20 is a schematic diagram illustrating a pixel array 20 according to an embodiment. Diagonally shaded light-shielding pixels 202 in FIG. 20 each include a polarizing element that polarizes in the direction of oblique lines. For example, the polarizing element may be a polarizing filter.

In this way, the amount of light can be changed by the provision of the polarizing element in the light-shielding pixel 202. If the polarizing element is provided, a state of polarization of reflected light on a display 4 is obtained in advance, thereby more accurately eliminating the influence of flare on the basis of a signal acquired in the light-shielding pixel 202.

As in the foregoing embodiments, the light-shielding pixel 202 may be configured to receive light such as W in any wavelength region.

### Fifth Embodiment

In the foregoing embodiments, a region receives light or partially blocks light for each pixel. The configuration is not limited thereto. For example, in a pixel 200, separate pixels that share an on-chip lens, a light receiving element, and a pixel circuit may be formed and a region may be provided to partially block light in each of the separate pixels.

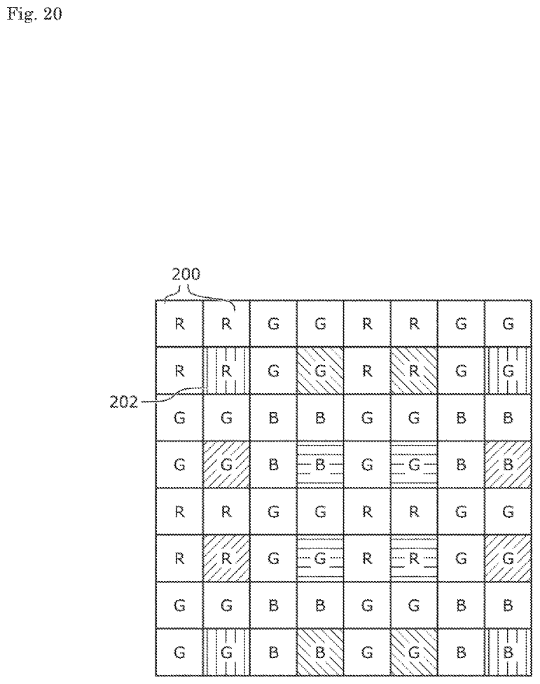

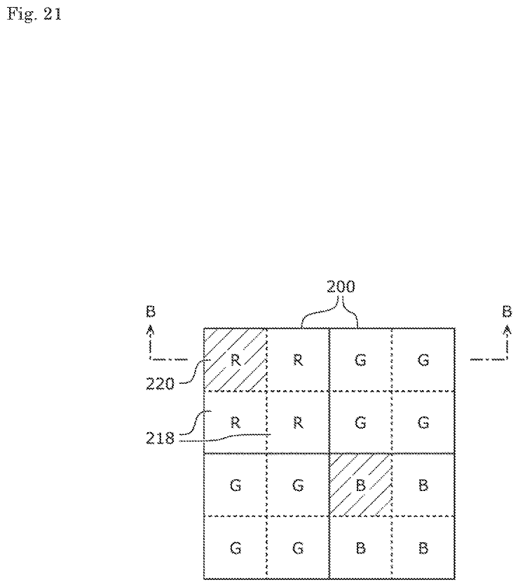

FIG. 21 illustrates an example of the pixels 200 and the separate pixels according to an embodiment. A solid-line border indicates a partition between the pixels, and a dotted-line border indicates a church between the separate pixels. As illustrated in FIG. 21, the pixel 200 includes a plurality of separate pixels 218 and a separate light-shielding pixel 220. As described above, the separate pixels 218 and the separate light-shielding pixel 220 of the same pixel 200 may share an on-chip lens, a light receiving element, and a pixel circuit.

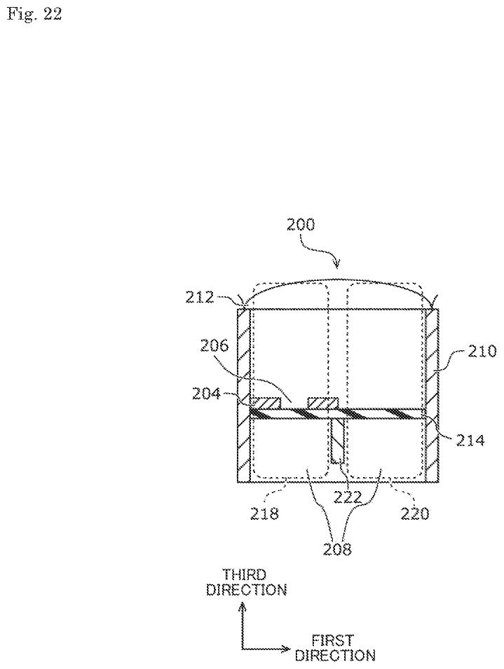

FIG. 22 is a cross-sectional view illustrating the R pixels taken along line B-B of FIG. 21. The pixel 200 includes the separate pixel 218 and the separate light-shielding pixel 220.

The separate pixel 218 includes a color filter 214, and the separate light-shielding pixel 220 further includes a light-shielding film 204. As illustrated in FIG. 22, light receiving regions 208 of the separate pixels 218 are provided with an element separating film 222. The element separating film 222 is a layer for separating the light receiving regions of the separate pixels 218 and is made of, for example, a metal or an insulator. Additionally, a memory region to form a memory region may be provided for each of the light receiving regions 208.

In the configuration including the separate pixels 218, some of the separate pixels 218 may be provided with the light-shielding films 204 to form the separate light-shielding pixels 220. As described above, a polarizing element may be provided instead of the light-shielding film 204.

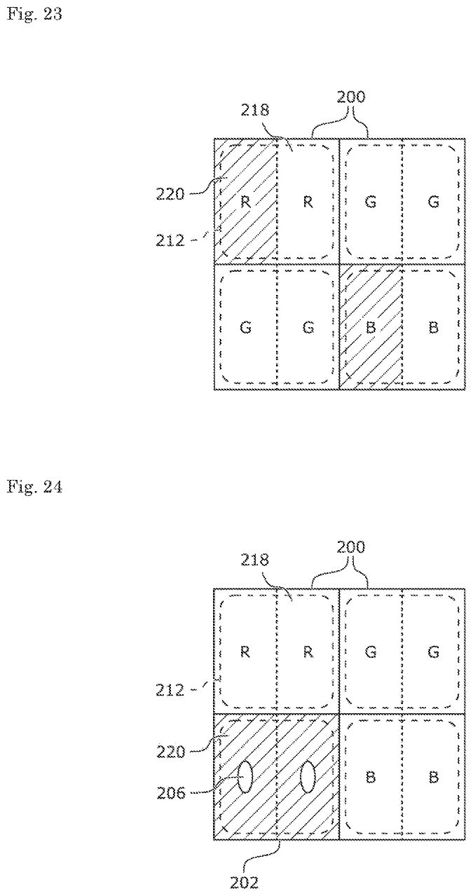

FIG. 23 illustrates another example of light shielding for the separate pixels. The number of separate pixels in the pixel 200 is not limited to 2×2. The number of separate pixels may be 2×1 or larger than 2×2. As illustrated in FIG. 23, an on-chip lens 212 may be disposed for each of the pixels 200.

FIG. 24 illustrates another example of light shielding for the separate pixels. As illustrated in FIG. 24, each of the pixel 200 and the light-shielding pixel 202 may constitute a separate pixel. Moreover, the separate light-shielding pixels 220 of the light-shielding pixel 202 may each include an opening 206. With this configuration, information about a phase difference between the outputs of the separate light-shielding pixels 220 in the light-shielding pixel 202, and the information about the phase difference can be used for determining diffracted light on a display 4.

The plurality of openings 206 in the light-shielding pixel 202 can be provided as illustrated in FIG. 24 without setting separate pixels. The number of openings 206 may be three or more.

According to the present embodiment, a light-shielding region may be provided in the separate pixel. As in the foregoing embodiments, the layouts of colors were illustrated as some examples. The configurations of the present disclosure are not limited to these examples. Moreover, the separate light-shielding pixel 220 may be formed by a polarizing element instead of the light-shielding film 204.

### Sixth Embodiment

The provision of the light-shielding pixels 202 and/or the separate light-shielding pixels 220 as in the foregoing embodiments allows the imaging element 2 to detect diffracted light on the display 4. The structure of the imaging element 2 is not limited to the detection of diffracted light.

For example, as described above, reflected light from an adjacent subject and reflected light from a remote subject can be distinguished from each other depending upon the size of an opening 206. For example, an object placed on a cover glass 5 and other objects have considerably different incident angles on the light receiving elements. Thus, a subject in contact with the cover glass 5 can be identified by an output from the light-shielding pixel 202.

With this configuration, the imaging element 2 can be used as an imaging element for fingerprint authentication. For example, if the imaging element 2 obtains reflected light of light emitted from the display 4 at a finger in contact with the cover glass 5, a fingerprint may be reconstructed by using an image signal outputted from the light-shielding pixel 202 or the separate light-shielding pixel 220. Reflected light becomes irregular at a point where an edge line of a fingerprint comes into contact with the cover glass 5, whereas in the region of a valley of the fingerprint, an incident angle and a reflection angle agree with each other on a surface of the cover glass 5. Thus, a proper fingerprint image can be reconstructed by acquiring the intensity of light received in the light-shielding pixel 202 where an incident angle is limited.

As described above, also in the case where an ultra-proximity image in contact with the cover glass 5 is obtained, the imaging element 2 including the light-shielding pixels 202 can be effectively used.

Instead of an ultra-proximity image, a subject image sufficiently close to the cover glass 5 can be properly obtained without automatic focusing. For example, when a bar code is held over the display 4, the bar code can be disposed at a distance within, for example, 10 cm from the display 4. Information about a subject relatively close to the display 4 may be reconstructed from information received by the light-shielding pixels 202. In the foregoing description, the distance is set within 10 cm. Any distances such as 5 cm or less may be set according to the circumstances.

According to the present embodiment, a nearby or ultra-proximity subject can be properly imaged in the imaging element 2 including the light-shielding pixels 202.

### Seventh Embodiment

In the sixth embodiment, nearby and ultra-proximity objects are read. The switching of the objects may be properly controlled by a user.

An electronic device 1 may control, for example, a macro photography mode, a fingerprint authentication mode, and a bar-code reading mode. These modes may be switched by the user.

For example, upon switching to the fingerprint authentication mode, a light source and reading pixels or the like may be properly controlled so as to capture a fingerprint image on the basis of outputs from light-shielding pixels 202. In other words, a signal processing unit 24 may control pixel values to easily acquire fingerprint information from signals outputted from pixels 200 and the light-shielding pixels 202. For example, an image may be configured by performing control such that a signal outputted from the light-shielding pixel 202 is multiplied by a gain of 1 or more to increase the influence of the signal outputted from the light-shielding pixel 202. After the reconstruction of a fingerprint image, the signal processing unit 24 may perform fingerprint authentication according to an ordinary method.

Also in the macro mode and the bar-code reading mode or the like, the signal processing unit 24 may control the reconstruction of an image to increase the influence of an output from the light-shielding pixel 202.

### Eighth Embodiment

In the foregoing embodiments, the light-shielding film, the absorbing film, and the polarizing element are used as light-shielding structures. The light-shielding structure is not limited thereto. In the present embodiment, light-shielding pixels and pixels applied with plasmon filters as different pixels are used.

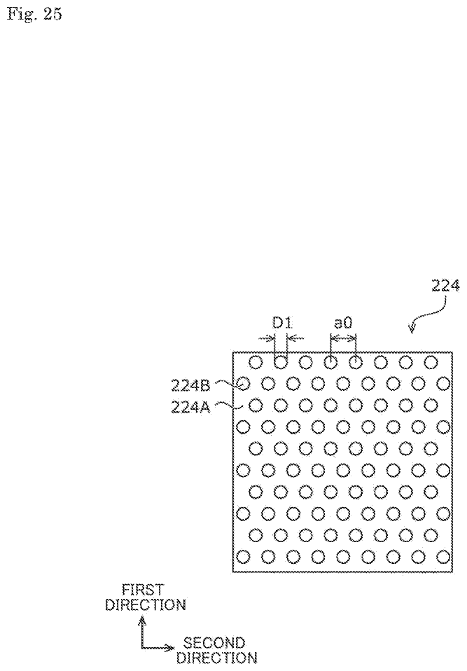

FIG. 25 illustrates an example of a plasmon filter. A plasmon filter 224 is formed with holes 224b disposed in a honeycomb pattern on a thin film 224a of a metal (or any electric conductor). With this structure, the plasmon filter 224 generates a plasmon resonance phenomenon based on an opening size D1 and a pitch a0 of the holes 224b.

Each of the holes 224b acts as a waveguide penetrating the thin film 224a. Typically, a waveguide has a cutoff frequency and a cutoff wavelength that are defined according to the size, e.g., the diameter and has the property of preventing the propagation of light at a frequency lower than the cutoff frequency (a wavelength longer than the cutoff frequency). The cutoff wavelength of the hole 224b depends upon the opening size D1 and the pitch a0 of the hole 224b. The larger the opening size D1, the longer the cutoff wavelength. The smaller the D1, the shorter the cutoff wavelength.

When light enters the thin film 224a, on which the holes 224b are periodically formed, with short periods not longer than the wavelength of light, light with a wavelength longer than the cutoff wavelength of the hole 224b passes through the thin film 224a. This phenomenon is called an anomalous transmission phenomenon of plasmon. This phenomenon is caused by excitation of surface plasmon on the border between the thin film 224a and a correlation film on the thin film 224a.

FIG. 26 is a graph indicating transmission wavelengths when the plasmon filter 224 is used. A solid line indicates a 250-nm pitch, a broken line indicate a 325-nm pitch, and a chain line indicates a 500-nm pitch. As indicated in the graph, the plasmon filter 224 cuts off light at the cutoff wavelength, operates as a waveguide mode at the cutoff wavelength or lower, and operates as a plasmon mode at the cutoff wavelength or higher.

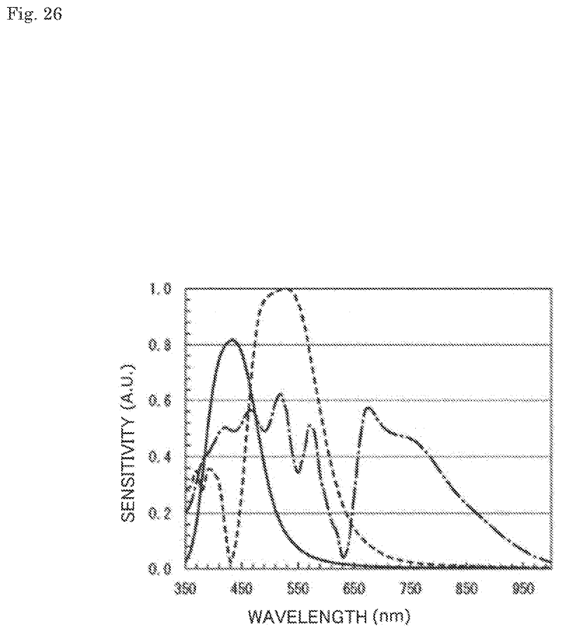

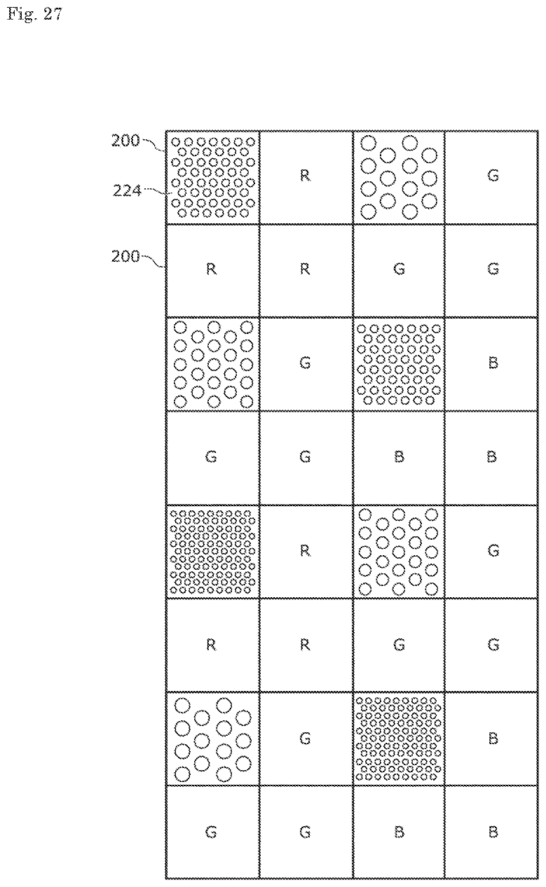

FIG. 27 illustrates a layout example of the plasmon filters 224. As illustrated in FIG. 27, the plasmon filters 224 having different characteristics may be disposed on pixels 200 as in the foregoing embodiments.

The provision of the plasmon filters 224 having different characteristics allows the estimation of a light source. For example, light with a wavelength other than the cutoff wavelengths of the plasmon filters 224 is received. The light source can be estimated on the basis of the received light.

The light source can be estimated by calculating the ratios of signals outputted from the pixels 200 where the plasmon filters 224 are disposed. For example, a color temperature may be estimated on the basis of the outputs of the plasmon filters 224 having different characteristics. The estimation is made by a signal processing unit 24. The signal processing unit 24 may further calculate a gain for each filter on the basis of the estimation result, and a value multiplied by the gain may be used as a color value of each pixel.

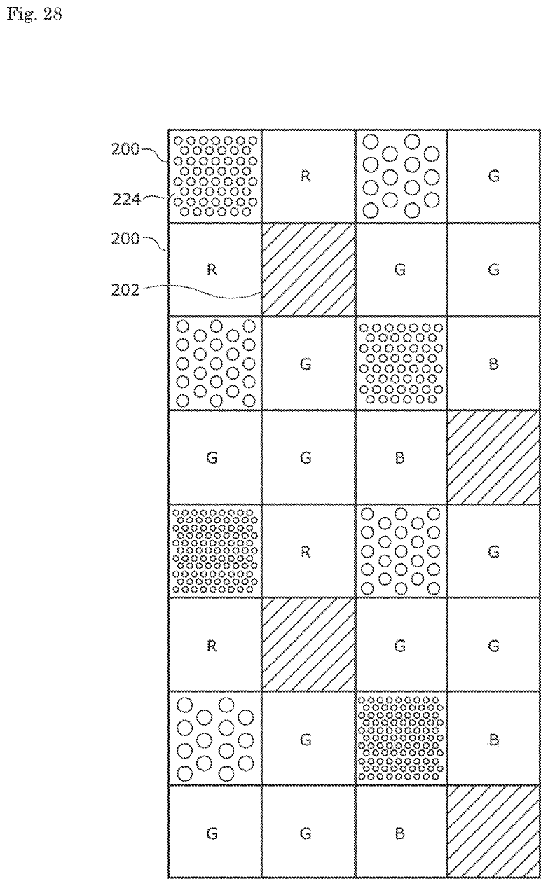

FIG. 28 illustrates an example of pixels arranged with the plasmon filters 224 and light-shielding pixels 202. As illustrated in FIG. 28, the plasmon filters 224 may be provided on pixels different from the light-shielding pixels 202. The use of the plasmon filters 224 allows the estimation of a light source as described above. Thus, if flare is removed from a state of the light source, the color components of flare can be more specifically analyzed.

If the light-shielding pixel 202 is used as a fingerprint sensor as another example, a masquerade can be prevented with reference to outputs from the pixels 200 where the plasmon filters 224 are disposed.

For example, the reflection of light on a living human skin considerably changes around a wavelength of 590 nm. Since the plasmon filters 224 having different characteristics (different cutoff wavelengths) are provided, an imaging element 2 can be configured to acquire multispectral information. Thus, in the acquired multispectral information, a reflection property at a wavelength around 590 nm can be obtained. By using the result, the signal processing unit 24 can determine whether a subject in contact with a cover glass 5 is a living body. Thus, an electronic device 1 including the imaging element 2 can perform fingerprint authentication and determine whether the fingerprint information is reflection from the living body.

If the pixels 200 include separate pixels, the plasmon filters 224 may be disposed on separate pixels 218. For example, if the plasmon filters 224 are provided, the imaging element 2 may acquire information about veins and information about hemoglobin instead of the fingerprint information. Alternatively, the imaging element 2 may acquire information about oxygen saturation in blood.

As another example, the imaging element 2 may acquire information about the irises of human eyes. In this case, light may be emitted to a display 4 without damaging human eyes.

In such a multispectral configuration, human biometric information other than fingerprints can be also acquired. For example, an authentication operation using the imaging element 2 may be implemented by acquiring one or more pieces of biometric information in the electronic device 1.

Some of the embodiments can be combined in proper forms. For example, as in the third embodiment, the electronic device 1 may include a plurality of imaging elements configured with separate pixels as in the fifth embodiment. In this case, interpolation can be performed such that the other output in a light-shielding pixel 202 or a separate light-shielding pixel 220 is not blocked. Likewise, other embodiments can be properly combined.

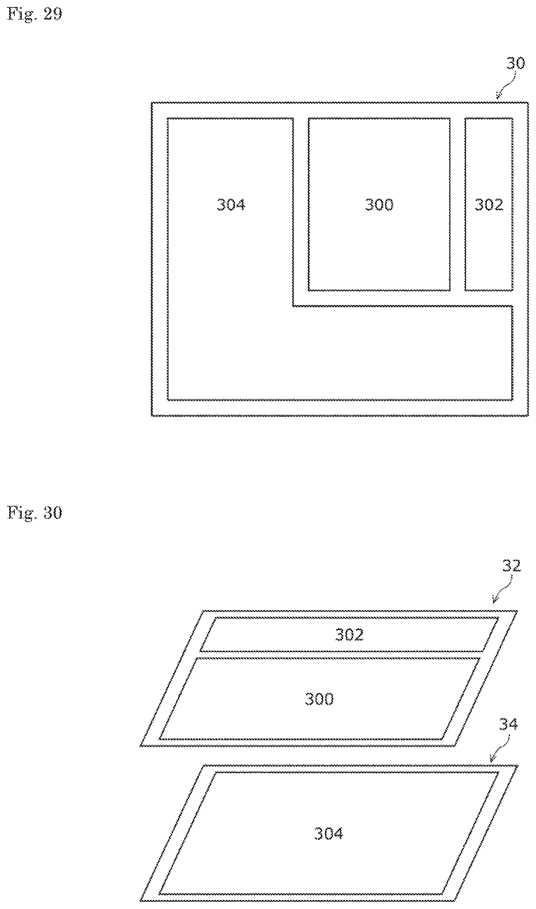

FIG. 29 illustrates an example of a substrate provided with the imaging element 2. A substrate 30 includes a pixel region 300, a control circuit 302, and a logic circuit 304. As illustrated in FIG. 29, the pixel region 300, the control circuit 302, and the logic circuit 304 may be provided on the same substrate 30.

The pixel region 300 is, for example, a region including the pixel array 20. The pixel circuit or the like may be properly provided in the pixel region 300 or another region that is not illustrated on the substrate 30. The control circuit 302 includes a control unit. For example, the logic circuit 304 may configured such that the A/D converter circuit of the signal processing unit 24 is provided in the pixel region 300 and outputs a converted digital signal to the logic circuit 304. Moreover, an image processing unit (e.g., a part of the circuit of the signal processing unit 24) may be provided in the logic circuit 304. The signal processing unit 24 and at least a part of the image processing unit may be placed on another signal processing chip provided at a different location from the substrate 30 or may be mounted in another processor.

FIG. 30 illustrates another example of the substrate provided with the imaging element 2. A first substrate 32 and a second substrate 34 are provided as substrates. The first substrate 32 and the second substrate 34 have a laminated structure in which signals can be properly transmitted and received via a connecting portion, e.g., a via hole. For example, the first substrate 32 may include the pixel region 300 and the control circuit 302 while the second substrate 34 may include the logic circuit 304.

FIG. 31 illustrates another example of the substrate provided with the imaging element 2. The first substrate 32 and the second substrate 34 are provided as substrates. The first substrate 32 and the second substrate 34 have a laminated structure in which signals can be properly transmitted and received via a connecting portion, e.g., a via hole. For example, the first substrate 32 may include the pixel region 300 while the second substrate 34 may include the control circuit 302 the logic circuit 304.

In FIGS. 29 to 31, a storage region may be provided in any region. In addition to these substrates, a substate for a storage region may be provided between the first substrate 32 and the second substrate 34 or under the second substrate 34.

The stacked substrates may be connected via a via hole as described above or may be connected by methods such as micro dump. The substrates can be stacked by any method of, for example, CoC (Chip on Chip), CoW (Chip on Wafer), or WoW (Wafer on Wafer).

### (Application Example of Electronic Device 1 or Imaging Element 2 According to the Present Disclosure)

### First Application Example

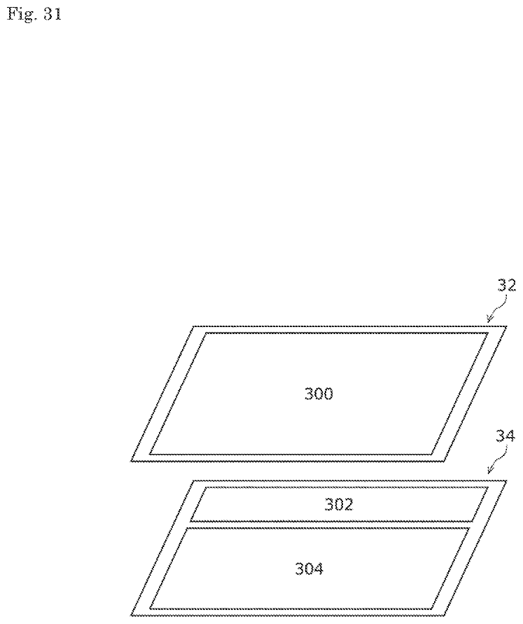

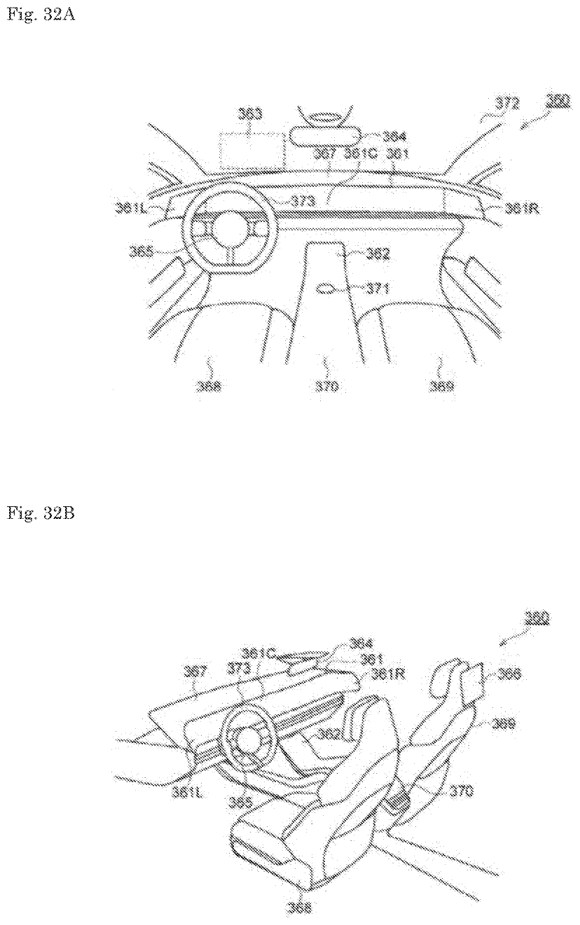

The electronic device 1 or the imaging element 2 according to the present disclosure can be used for various purposes. FIGS. 32A and 32B illustrate the internal configuration of a vehicle 360, which is a first application example of the electronic device 1 including the imaging element 2 according to the present disclosure. FIG. 32A illustrates a state of the interior of the vehicle 360 from the rear to the front of the vehicle 360. FIG. 32B illustrates a state of the interior of the vehicle 360 diagonally from the rear to the front of the vehicle 360.

The vehicle 360 in FIGS. 32A and 32B has a central display 361, a console display 362, a head-up display 363, a digital rear mirror 364, a steering wheel display 365, and a rear entertainment display 366.

The central display 361 is disposed on a dashboard 367 so as to face a driver's seat 368 and a passenger seat 369. In the example of FIG. 32, the horizontally oriented central display 361 extends from the driver's seat 368 to the passenger seat 369. The central display 361 may have any screen size at any location. The central display 361 can display information detected by various sensors. As specific examples, the central display 361 can display an image captured by an image sensor, a distance image ahead of the vehicle and to an obstacle on the side, the distance image being measured by a ToF sensor, and a passenger's body temperature detected by an infrared sensor. The central display 361 can be used for displaying, for example, at least one of safety-related information, operation-related information, a lifelog, health-related information, authentication/identification-related information, and entertainment-related information.

The safety-related information includes dozing detection, looking-aside detection, the detection of mischief by kids on board, seat-belt usage, and the detection of passengers left behind. The safety-related information is detected by, for example, a sensor placed on the back side of the central display 361. For the operation-related information, the gestures of passenger's operations are detected by using a sensor. The detected gestures may include the operations of various kinds of equipment in the vehicle 360. For example, the operations of air-conditioning equipment, a navigation system, an audio-visual system, and a lighting system. The lifelog includes the lifelogs of all passengers. For example, the lifelog includes the action records of passengers on board. The lifelog is obtained and stored, allowing confirmation of a state of passengers at the time of an accident. For the health-related information, the body temperature of a passenger is detected by using a temperature sensor, and the state of health of a passenger is estimated on the basis of the detected body temperature. Alternatively, a passenger's face may be imaged by using an image sensor, and then the state of health of the passenger may be estimated from an image of a facial expression. Furthermore, through automatic speech conversations with a passenger, the state of health of the passenger may be estimated on the basis of the contents of the response of the passenger. The authentication/identification-related information includes a remote keyless entry function for performing face authentication using a sensor and an automatic adjustment function of a seat height or position in face authentication. The entertainment-related information includes the function of detecting passenger operation information about an audio-visual system by using a sensor, and the function of recognizing the face of a passenger through a sensor and providing suitable contents for the passenger through the audio-visual system.

The console display 362 can be used for displaying, for example, lifelog information. The console display 362 is disposed near a shift lever 371 of a central console 370 between the driver's seat 368 and the passenger seat 369. Also on the console display 362, information detected by various sensors can be displayed. Furthermore, the console display 362 may display an image captured around the vehicle by an image sensor or a distance image to an obstacle around the vehicle.

The head-up display 363 is virtually displayed at the front of a windshield 372 in front of the driver's seat 368. The head-up display 363 can be used for displaying, for example, at least one of safety-related information, operation-related information, a lifelog, health-related information, authentication/identification-related information, and entertainment-related information. In many cases, the head-up display 363 is virtually disposed in front of the driver's seat 368 and thus is suitable for displaying information directly related to the operations of the vehicle 360, for example, a speed or an amount of remaining fuel (battery) of the vehicle 360.

The digital rear mirror 364 can display a state of a passenger in the rear seat as well as the rear of the vehicle 360. Thus, by placing a sensor on the back side of the digital rear mirror 364, the digital rear mirror 364 can be used for displaying, for example, lifelog information.

The steering wheel display 365 is disposed around the center of a steering wheel 373 of the vehicle 360. The steering wheel display 365 can be used for displaying, for example, at least one of safety-related information, operation-related information, a lifelog, health-related information, authentication/identification-related information, and entertainment-related information. The steering wheel display 365, in particular, is placed near the hands of a driver and thus is suitable for displaying lifelog information such as a body temperature of the driver or information about the operations of an audio-visual and air-conditioning equipment.

The rear entertainment display 366 is attached to the back side of the driver's seat 368 or the passenger seat 369 and allows a passenger in the rear seat to view information. The rear entertainment display 366 can be used for displaying, for example, at least one of safety-related information, operation-related information, a lifelog, health-related information, authentication/identification-related information, and entertainment-related information. The rear entertainment display 366, in particular, is placed in front of a passenger in the rear seat and thus displays information related to the passenger in the rear seat. For example, the rear entertainment display 366 may display information about the operations of an AV system or air-conditioning equipment or the result of measuring a body temperature or the like of a passenger in the rear seat by a temperature sensor.

As described above, the sensor is placed on the back side of the electronic device 1, thereby measuring a distance to an object around the vehicle. Optical distance measurement methods are broadly classified as a passive type and an active type. The passive type measures a distance by receiving light from an object without projecting light onto the object from a sensor. The passive type is, for example, a lens focal method, a stereo method, or a monocular vision method. The active type measures a distance by projecting light onto an object and receiving reflected light from the object by a sensor. The active type is, for example, an optical radar system, an active stereo system, an illuminance difference stereo method, a moire topography method, or interferometry. The electronic device 1 according to the present disclosure is applicable to any one of the distance measurement methods. By using the sensor placed on the back side of the electronic device 1 according to the present disclosure, a distance can be measured as the passive type or the active type.

### Second Application Example

The electronic device 1 including the imaging element 2 according to the present disclosure is applicable to displays mounted on various electronic devices as well as various displays used for vehicles.

FIG. 33A is a front view illustrating a digital camera 310 as a second application example of the electronic device 1. FIG. 33B is a rear view of the digital camera 310. The digital camera 310 in FIGS. 33A and 33B is an example of a single-lens reflex camera including a replaceable lens 121. This example is also applicable to a camera including an irreplaceable lens 121.

A photographer holding a grip 313 of a camera body 311 of the camera in FIGS. 33A and 33B determines a composition through an electronic view finder 315 and presses the shutter while adjusting the focus, so that shooting data is stored in the memory of the camera. On the back side of the camera, as illustrated in FIG. 33B, a monitor screen 316 and the electronic view finder 315 are provided. The monitor screen 316 displays, for example, shooting data or live images. Moreover, a sub screen for displaying setting information such as a shutter speed and an exposure value may be provided on the top face of the camera.

By placing a sensor on the back side where the monitor screen 316, the electronic view finder 315, and the sub screen are provided to be used for the camera, the camera can be used as the electronic device 1 according to the present disclosure.

### Third Application Example

The electronic device 1 according to the present disclosure is also applicable to a head mount display (hereinafter referred to as an HMD). The HMD can be used for, for example, VR, AR, MR (Mixed Reality), or SR (Substitutional Reality).

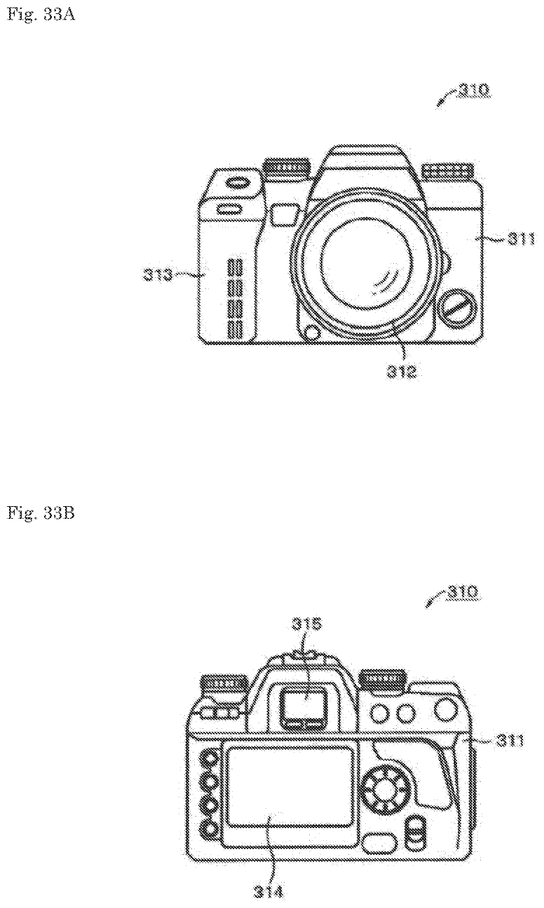

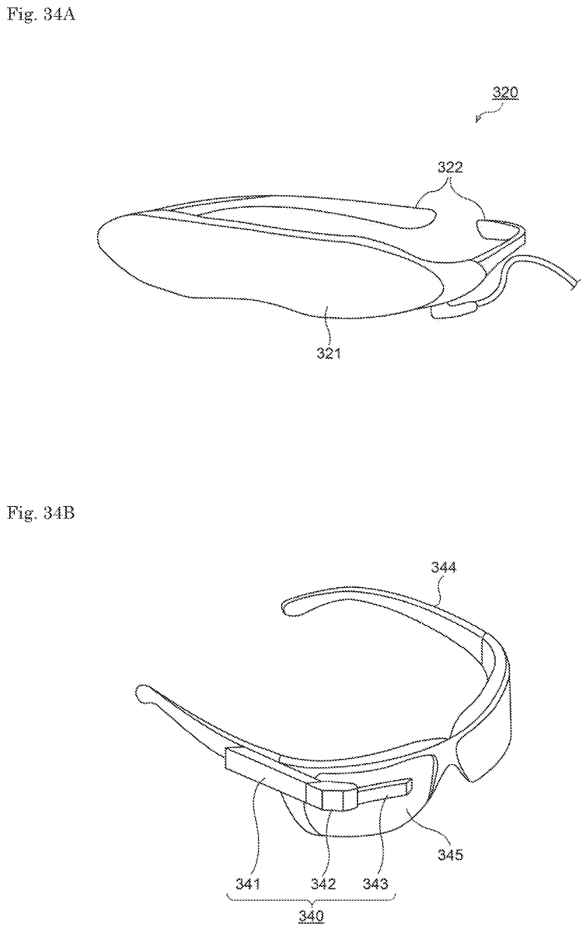

FIG. 34A is an outside drawing illustrating an HMD 320 as a third application example of the electronic device 1. The HMD 320 in FIG. 34A has fitting members 322 that place the HMD 320 over human eyes. The fitting members 322 are fixed on, for example, human ears. A display device 321 is provided inside the HMD 320. A wearer of the HMD 320 can view three-dimensional video or the like through the display device 321. The HMD 320 includes, for example, a radio communication function and an acceleration sensor and can switch three-dimensional videos or the like displayed on the display device 321 according to the posture and gesture of the wearer.

Moreover, the HMD 320 may be provided with a camera to capture an image around the wearer, and display a composite image of the image captured by the camera and an image generated by a computer on the display device 321. For example, a camera is placed on the back side of the display device 321 viewed by the wearer of the HMD 320, and an image around the eyes of the wearer is captured by the camera and is displayed on another display provided on the outer surface of the HMD 320, allowing persons around the wearer to recognize a facial expression and an eye movement of the wearer in real time.

Various types of HMDs may be used as the HMD 320. For example, as illustrated in FIG. 34B, the electronic device 1 according to the present disclosure is also applicable to a smart glass 340 that projects various kinds of information on glasses 344. The smart glass 340 in FIG. 34B includes a body part 341, an arm part 342, and a lens-barrel part 343. The body part 341 is connected to the arm part 342. The body part 341 is detachably attached to the glasses 344. The body part 341 includes a control board for controlling the operations of the smart glass 340 and a display part. The body part 341 and the lens-barrel are coupled to each other via the arm part 342. The lens-barrel part 343 radiates image light, which is emitted from the body part 341 through the arm part 342, onto a lens 345 of the glasses 344. The image light enters a human eye through the lens 345. The wearer of the smart glass 340 in FIG. 34B can recognize various kinds of information emitted from the lens-barrel part 343 as well as circumstances around the wearer as in the case where the wearer wears ordinary glasses.

### Fourth Application Example

The electronic device 1 according to the present disclosure is also applicable to a television set (hereinafter referred to as a TV). Recent TVs tend to have frames with minimum dimensions in view of the miniaturization and designs. Thus, if a camara for shooting of a viewer is provided for a TV, the camera is desirably placed on the back side of a display panel 331 of the TV.

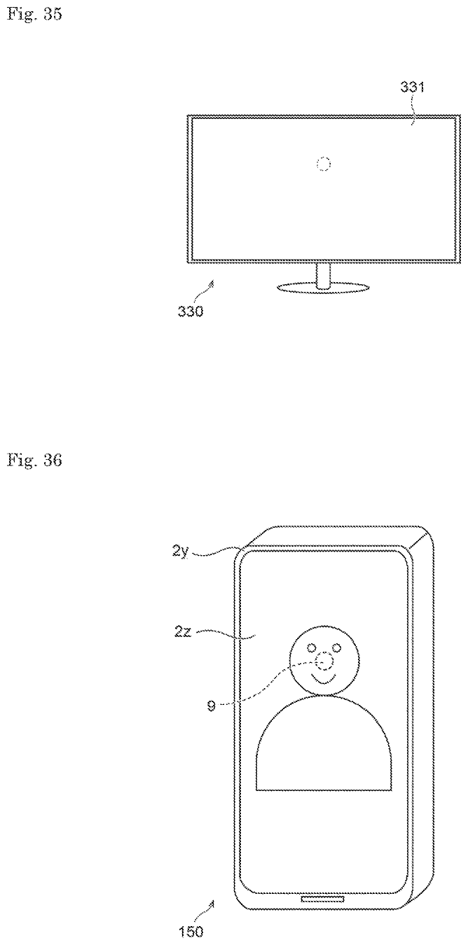

FIG. 35 is an outside drawing illustrating a TV 330 as a fourth application example of the electronic device 1. The TV 330 in FIG. 35 has a minimum frame and a display area substantially over the front side of the TV. The TV 330 includes a sensor, e.g., a camera for capturing an image of a viewer. The sensor of FIG. 35 is disposed on the back side of a part (e.g., a part indicated by a broken line) of the display panel 331. As the sensor, various sensors such as an image sensor, a sensor for face authentication, a sensor for measuring a distance, and a temperature sensor are applicable. Multiple kinds of sensors may be disposed on the back side of the display panel 331 of the TV 330.

As described above, according to the electronic device 1 of the present disclosure, an image sensor module can be placed on the back side of the display panel 331, thereby eliminating the need for placing a camera or the like on the frame. This can downsize the TV 330 and prevent the frame from interfering with the design.

### Fifth Application Example

The electronic device 1 according to the present disclosure is also applicable to a smartphone or a cellular phone. FIG. 36 is an outside drawing illustrating a smartphone 350 as a fifth application example of the electronic device 1. In the example of FIG. 36, a display surface 2z extends close to the outside dimensions of the electronic device 1, and a bezel 2y around the display surface 2z has a width of several mm. Typically, the bezel 2y has a front camera. In FIG. 36, as indicated by a broken line, an image sensor module 9 acting as a front camera is disposed on, for example, the back side of substantially a central portion of the display surface 2z. The front camera provided thus on the back side of the display surface 2z eliminates the need for placing a front camera on the bezel 2y, thereby reducing the width of the bezel 2y.

The foregoing embodiments may be configured as follows:

(1) An imaging element including:
pixels, each including a light receiving element that photoelectrically converts incident light and outputs an analog signal based on light intensity; and a pixel array in which the pixels are disposed in an array,
wherein
some of the pixels belonging to the pixel array have a light-shielding structure for blocking part of light entering the light receiving element.
   (2)

The imaging element according to (1), wherein the light-shielding structure limits an incident angle of light entering the light receiving element of the pixel having the light-shielding structure.

(3)

The imaging element according to (2), wherein the light-shielding structure is a light-shielding film provided for the light receiving element.

(4)

The imaging element according to (3), wherein, in the pixels, the light-shielding structure is formed with an opening having a size equal to or smaller than 25% of the area of the surface of the light receiving element.

(5)

The imaging element according to (3), wherein an opening formed by the light-shielding structure is identical or different in size among the pixels.

(6)

The imaging element according to (3) or (5), wherein the opening formed by the light-shielding structure is provided at the same relative position or different relative positions in the pixels.

(7)

The imaging element according to any one of (3) to (6), wherein in the pixel, one or more openings are formed by the light-shielding structure.

(8)

The imaging element according to (2), wherein the light-shielding structure is a polarizer provided for the light receiving element.

(9)

The imaging element according to (2), wherein the pixels different from the pixels having the light-shielding structure include the pixel having a plasmon filter disposed on the entry face side of the light receiving element.

(10)

The imaging element according to any one of (2) to (9), wherein the pixels having the light-shielding structure are disposed without being adjacent to each other in the pixel array.

(11)

The imaging element according to (10), wherein the pixels having the light-shielding structure are periodically disposed in the pixel array.

(12)

The imaging element according to any one of (2) to (11), wherein each of the pixels includes an on-chip lens, and
the pixel array includes a module lens.
   (13)

The imaging element according to any one of (2) to (12), wherein the pixel include separate pixels obtained by dividing the light receiving element belonging to the pixel into a plurality of pixels, and
the pixel having the light-shielding structure is provided with the light-shielding structure for at least one of the separate pixels.
   (14)

The imaging element according to any one of (2) to (13), further including a signal processing circuit that converts an analog signal outputted from the light receiving element into a digital signal.

(15)

The imaging element according to (14), wherein the signal processing circuit detects a shape of a light source on the basis of an output from the pixel having the light-shielding structure.

(16)

The imaging element according to (15), wherein the signal processing circuit corrects the digital signal on the basis of the shape of the light source.

(17)

The imaging element according to (14), wherein if the plasmon filter is provided, the signal processing circuit estimates the light source on the basis of an output from the pixel having the light-shielding structure.

(18)

An electronic device including: the imaging element according to any one of (14) to (17); and
a display that has a display surface for displaying information on the entry face side of the imaging element,
wherein
the imaging element converts, by photoelectric conversion, light received through the display.
   (19)

The electronic device according to (18), wherein the pixel is provided such that an incident angle allowing the entry of light is controlled to 50% or less of a typical incident angle by the light shielding structure, and
imaging information about an adjacent object is generated on the basis of an output from the pixel having the light-shielding structure.
   (20)

The electronic device according to (19), wherein biometric information is obtained through the display on the basis of an output from the pixel having the light-shielding structure.

(21)

The electronic device according to (20), wherein the biometric information is information including any one of a fingerprint, an iris, a vein, a skin, hemoglobin, and oxygen saturation.

(22)

The electronic device according to any one of (18) to (21), wherein image quality deteriorated by the display is restored on the basis of an output from the pixel having the light-shielding structure.

(23)

The electronic device according to any one of (18) to (22), wherein information about a bar code is acquired on the basis of an output from the pixel having the light-shielding structure.

(24)

The electronic device according to any one of (18) to (23), wherein a plurality of the imaging elements are provided.

(25)

The electronic device according to (24), wherein in the plurality of the imaging elements, the wiring layout of the display in at least one of the imaging elements is different from the wiring layout of the display in the other imaging elements.

The aspects of the present disclosure are not limited to the embodiments described above and include various modifications that are conceivable, and effects of the present disclosure are not limited to the above-described content. Constituent elements of the embodiments may be appropriately combined for an application. In other words, various additions, changes, and partial deletions can be performed in a range not departing from the conceptual idea and spirit of the present disclosure derived from content specified in the claims and equivalents thereof.

### REFERENCE SIGNS LIST

1 Electronic device
1a Display region 1b Bezel
2 Imaging element
3 Component layer
4 Display
5 Cover glass
20 Pixel array
200 Pixel
202 Light-shielding pixel
204 Light-shielding film
206 Opening
208 Light receiving region
210 Light-shielding wall
212 On-chip lens
214 Color filter
216 ND filter
218 Separate pixel
220 Light-shielding pixel
222 Element separating film
224 Plasmon filter
224a Thin film 224b Hole
22 Storage unit
24 Signal processing unit
26 Output unit

1. An imaging element comprising: pixels, each including a light receiving element that photoelectrically converts incident light and outputs an analog signal based on light intensity; and
a pixel array in which the pixels are disposed in an array,
wherein
some of the pixels belonging to the pixel array have a light-shielding structure for blocking part of light entering the light receiving element, and the light-shielding structure limits an incident angle of light entering the light receiving element.

2. The imaging element according to claim 1, wherein the light-shielding structure is a light-shielding film provided for the light receiving element.

3. The imaging element according to claim 2, wherein, in the pixels, the light-shielding structure is formed with an opening having a size equal to or smaller than 25% of an area of a light receiving surface of the light receiving element, the opening being formed by the light-shielding structure.

4. The imaging element according to claim 2, wherein an opening formed by the light-shielding structure is identical or different in size among the pixels, each being provided with the light-shielding film.

5. The imaging element according to claim 2, wherein an opening formed by the light-shielding structure is provided at the same relative position or different relative positions in the pixels, each being provided with the light-shielding film.

6. The imaging element according to claim 1, wherein the light-shielding structure is a polarizer provided for the light receiving element.

7. The imaging element according to claim 1, wherein the pixels having the light-shielding structure are disposed without being adjacent to each other in the pixel array.

8. The imaging element according to claim 7, wherein the pixels having the light-shielding structure are periodically disposed in the pixel array.

9. The imaging element according to claim 1, wherein each of the pixels includes an on-chip lens, and
the pixel array includes a module lens.

10. The imaging element according to claim 1, wherein the pixel include separate pixels obtained by dividing the light receiving element belonging to the pixel into a plurality of pixels, and
the pixel having the light-shielding structure is provided with the light-shielding structure for at least one of the separate pixels.

11. The imaging element according to claim 1, further comprising a signal processing circuit that converts an analog signal outputted from the light receiving element into a digital signal.

12. The imaging element according to claim 11, wherein the signal processing circuit detects a shape of a light source on a basis of an output from the pixel having the light-shielding structure, and
the signal processing circuit corrects the digital signal on a basis of the shape of the light source.

13. The imaging element according to claim 11, wherein the pixels different from the pixels having the light-shielding structure include the pixel having a plasmon filter disposed on an entry face side of the light receiving element, and
the signal processing circuit estimates a light source on a basis of an output from the pixel provided with the plasmon filter.

14. An electronic device comprising: the imaging element according to claim 11; and
a display that has a display surface for displaying information on an entry face side of the imaging element,
wherein
the imaging element converts, by photoelectric conversion, light received through the display.

15. The electronic device according to claim 14, wherein the pixel is provided such that an incident angle allowing entry of light is controlled to 50% or less of a typical incident angle by the light-shielding structure, and
imaging information about an adjacent object is generated on a basis of an output from the pixel having the light-shielding structure.

16. The electronic device according to claim 15, wherein biometric information is obtained through the display on the basis of an output from the pixel having the light-shielding structure.

17. The electronic device according to claim 15, wherein image quality deteriorated by the display is restored on the basis of an output from the pixel having the light-shielding structure.

18. The electronic device according to claim 15, wherein information about a bar code is acquired on the basis of an output from the pixel having the light-shielding structure.

19. The electronic device according to claim 15, wherein a plurality of the imaging elements are provided.

20. The electronic device according to claim 19, wherein in the plurality of the imaging elements, a wiring layout of the display in at least one of the imaging elements is different from a wiring layout of the display in the other imaging elements.
